(19) United States
(12) Patent Application Publication
(10) Pub. No.: US 2022/0348422 A1
(43) Pub. Date: Nov. 3, 2022

(54) SUBSTRATE CARRIER WITH CENTERING FUNCTION

(71) Applicant: Singulus Technologies AG, Kahl am Main (DE)

(72) Inventors: Reiner ROHRMANN, Freigericht (DE); Stefan KEMPF, Alzenau (DE)

(21) Appl. No.: 17/720,226

(22) Filed: Apr. 13, 2022

(30) Foreign Application Priority Data
Apr. 30, 2021 (DE) 10 2021 002 293.9

(51) Int. Cl. B65G 49/06; C03B 32/00

(52) U.S. Cl. CPC B65G 49/061; C03B 32/00; C03C 17/002

(57) ABSTRACT

The present invention relates to a substrate carrier for accommodating and transporting a substrate, to a changing station comprising such a substrate carrier as well as to a method for treating a substrate.

### CROSS-REFERENCE TO RELATED APPLICATIONS

This present application claims priority to German Patent Application No. 10 2021 002 293.9, filed Apr. 30, 2021, which is hereby incorporated by reference in its entirety.

### FIELD

The present invention relates to a substrate carrier for accommodating and transporting a substrate, to a changing station comprising such a substrate carrier as well as to a method for treating a substrate.

### BACKGROUND

In a variety of industrial processes, substrates such as, for example, glass plates, wafers etc. are treated, for example coated, in a variety of ways. In order to move the substrates to different process stations, substrate carriers are usually used to accommodate and transport a substrate (or a plurality of substrates). In some processes, such as, for example, coating, it can be crucial that the orientation of the substrate relative to the substrate carrier is clearly defined and precisely maintained. Problems can arise, on the one hand, from any tolerances of the substrates or, on the other hand, from heating problems during a specific process step if the substrate carrier and substrate expand to different extents.

Therefore, various devices for centering a substrate in a substrate carrier have already been described in the prior art, cf., for example, US 2014/0077431 A1 and JP 2010-103226 A. However, the centering devices described therein have certain disadvantages. For example, US 2014/0077431 A1 proposes to clamp the substrate between spring-loaded projections and alignment pins, which entails that an expansion of the substrate (for example during heating) is only possible asymmetrically, namely exclusively in the direction of the springs. While JP 2010-103226 A allows a symmetrical operation in this respect, the force provided for centering is based on the weight force of the substrate, which has several disadvantages. On the one hand, the exact vertical position depends on the substrate width, which results in inaccurate positioning in the case of corresponding tolerances. On the other hand, a certain lateral frictional force will always be effective when lifting the substrates, which is not desirable.

### BRIEF SUMMARY

It is therefore an object of the present invention to provide a substrate carrier improved in this respect for accommodating and transporting a substrate. This object is achieved by a substrate carrier according to claim 1.

The substrate carrier according to the invention comprises a centering device adapted to center the substrate along a first axis, wherein the centering device comprises two inwardly preloaded springs opposite each other. The provision of two springs opposite each other enables symmetrical centering, which ensures centering of the substrate with respect to the substrate carrier even at different temperatures and different expansion characteristics of the substrate carrier and the substrate. Furthermore, the inwardly preloaded springs enable a defined centering force that is independent of the weight of the substrate.

The substrate carrier according to the invention is adapted to accommodate and transport any substrates. However, large-area glass substrates with an area of at least 1 m² and a thickness of preferably less than 5 mm and particularly preferably less than 3 mm are particularly preferred.

The substrate carrier according to the invention is not limited to centering an individual substrate in a substrate carrier. A substrate carrier can be adapted to accommodate a plurality of substrates and then comprises a plurality of the described centering devices and/or locking devices.

With respect to the symmetrical action of force, the two inwardly preloaded springs opposite each other are preferably arranged on a straight line that is parallel to the first axis. The first axis, in turn, is preferably parallel to a side edge of a substrate accommodated in the substrate carrier and preferably oriented substantially horizontally.

In principle, any springs can be used for the centering device, wherein preferably the two springs opposite each other have the same spring rigidity. The springs preferably comprise a contact area which is provided to come into contact with the substrate, wherein the contact area has a radius of curvature of at least 5 mm, preferably at least 10 mm and particularly preferably at least 20 mm. It is self-evident that, due to said curvature of the contact area, not the entire contact area can come into contact with the substrate. Rather, depending on the size of the substrate and the spring position of the spring, only a very small portion of the contact area (for example, a contact point or contact line) will come into contact with the substrate. Therefore, the term contact area refers to the part of the spring that realistically could come into contact with a substrate in the case of different substrate sizes and different spring positions.

During a respective process step, the substrate is clamped in the substrate carrier by means of the opposite springs and is being held in a centered position by the spring forces of the two springs. However, in order to be able to insert the substrate into the substrate carrier, the contact areas of the springs should be moved outwards relative to the contact situation in order to leave sufficient clearance for the insertion of the substrate. For this purpose, it is particularly preferred that each of the springs comprises an accommodating area for a first movement element and that the springs can be moved outwards by means of the first movement elements. The movement elements can be part of a changing station which is described in detail below and by means of which the springs can be opened and closed, preferably automatically.

According to the invention, the substrate carrier can further comprise a substrate that is accommodated in the substrate carrier. In the contact area in the direction of the substrate thickness (i.e., perpendicular to the substrate surface), the springs preferably have an extension that is greater than the thickness of the substrate. Thereby, for example, deformations of the substrate during temperature variations can be compensated for in that the contact area of the respective spring can still make contact with a substrate which is bent upwards or downwards and thus centering is ensured. Preferably, the ratio between the extension of the contact area and the thickness of the substrate is at least 1.5 and particularly preferably at least 2. Preferably, the extension of the spring in the contact area in the direction of the substrate thickness is at least 2 mm, preferably at least 3 mm.

Depending on the process, the substrates can be differently oriented in the substrate carrier according to the invention. According to a first variant, the substrate is oriented substantially vertically in the substrate carrier, wherein the substrate rests on the substrate carrier at its lower edge extending parallel to the first axis. In this regard, a substantially vertical orientation encompasses not only a directly vertical arrangement, but also an arrangement that is slightly tilted with respect to the perfectly vertical orientation, i.e., by up to +/−10°. In other words, the substrate (or its surface) accommodated in the substrate carrier can assume an angle between 80° and 100° with respect to the horizontal. Due to the fact that the substrate rests on the substrate carrier at its lower edge, a static friction force exists between the lower edge of the substrate and the substrate carrier. It is preferred that a decentration of the substrate along the first axis by 2 mm, preferably by 1 mm and particularly preferably by 0.5 mm, generates a resultant force of the two springs onto the substrate that is greater than said static friction force. Thus, if the substrate is displaced by a corresponding offset from the position that is central with respect to the substrate carrier (for example, because the different expansion of the substrate carrier and the substrate during heating results in an asymmetric positioning of the substrate in the substrate carrier), the spring forces of the two springs result in a resultant force that is large enough to overcome the static friction force between the substrate and the substrate carrier and, accordingly, to move the substrate back to its central position. It is preferred that the coefficient of static friction is less than 0.2, preferably less than 0.15 and particularly preferably less than 0.1.

If the substrate carrier according to the invention is to be used, for example, as part of a coating process, it is further preferred that the substrate carrier comprises a masking for partially covering the substrate, wherein the masking preferably is an integral part of the substrate carrier. If such a masking is present, the centering of the substrate with respect to the substrate carrier (and then also with respect to the masking) is particularly important, since otherwise edges that are too large or too small may be covered by the masking in edge regions of the substrate.

Furthermore, a plurality of locking devices can be provided at the substrate carrier, which are adapted to hold the substrate in the substrate carrier in a form-fitting and force-free manner. Preferably, at least one such locking device is provided on each edge of the substrate.

In order to center the substrate not only along a first axis but with respect to two axes, preferably arranged perpendicularly to each other, the substrate carrier preferably comprises a further centering device adapted to center the substrate along a second axis, wherein the further centering device comprises two pairs of inwardly preloaded springs opposite each other. Preferably, the further centering device and its springs comprise the same features as discussed above with respect to the first centering device and its springs. However, it is preferred that the further centering device, unlike the first centering device, comprises two pairs of inwardly preloaded springs opposite each other, i.e. a total of four springs. This is intended to prevent the substrate from twisting or tilting relative to the substrate carrier. The provision of two centering devices comprising a total of six springs is in particular advantageous when the substrate is oriented substantially horizontally in the substrate carrier, wherein the substrate rests on the substrate carrier at its side edges. Again, a perfect horizontal orientation is not required, but rather a deviation of up to 20° from the horizontal orientation is tolerated.

Analogous to the vertical orientation discussed above, a static friction force exists between the side edges of the substrate and the substrate carrier in the case of the horizontal orientation, wherein preferably a decentration of the substrate along the first axis or the second axis by 2 mm, preferably by 1 mm and particularly preferably by 0.5 mm, generates a resultant force of the respective springs onto the substrate that is greater than the static friction force. Again, the coefficient of static friction is preferably less than 0.2, more preferably less than 0.15 and particularly preferably less than 0.1.

The present invention further relates to a changing station with a substrate carrier as described above. The changing station is adapted to exchange the substrates in the substrate carrier, i.e., to insert substrates in the substrate carrier and to remove them from the substrate carrier after the respective process. As discussed above, preferably each of the springs comprises an accommodating area for a first movement element. Accordingly, the changing station comprises two or more first movement elements adapted to move the springs outwards. This is preferably done automatically, for example with the aid of an actuator of the changing station.

Furthermore, the changing station can comprise a plurality of locking devices adapted to hold the substrate in the substrate carrier in a form-fitting and force-free manner. Said locking devices can also be moved, preferably automatically, with the aid of an actuator, for example.

The present invention is further directed to a method for treating a substrate. According to the invention, a substrate is first inserted into a substrate carrier as described above, preferably with the aid of the changing station discussed above. Subsequently, while the substrate is in the substrate carrier, the substrate is treated, for example heated, cleaned, polished, coated, loaded, etc.

Prior to the insertion of the substrate into the substrate carrier, the springs of the centering device are moved outwards, preferably automatically. If the substrate carrier comprises the locking devices discussed above, which are adapted to hold the substrate in the substrate carrier in a form-fitting and force-free manner, the locking devices preferably are also opened, preferably automatically, prior to the insertion of the substrate into the substrate carrier. In this state, i.e. with the locking devices open and the springs moved outwards, the substrate can be inserted into the substrate carrier without any problems. After the insertion of the substrate, the springs of the centering device are then moved inwards, preferably automatically, and, as the case may be, the locking devices are closed, preferably automatically. The substrate is then held in the substrate carrier in a form-fitting and force-free manner and positioned in a central position by the springs of the centering device. The treatment of the substrate can then take place in this state.

After the process step (or, if applicable, a plurality of process steps), the substrate is removed again from the substrate carrier. Both the insertion and the removal of the substrate are preferably performed with the changing station discussed above.

Analogous to the procedure of the insertion, the springs of the centering device are moved outwards, preferably automatically, prior to the removal of the substrate, and the optional locking devices are opened, preferably automatically, prior to the removal of the substrate.

As mentioned above, the invention is particularly advantageous when the substrate carrier and the substrate behave differently during heating or cooling. It is therefore preferred that the substrate carrier and/or the substrate is heated from a first temperature to a second temperature between the introduction of the substrate and the treatment of the substrate and/or during the treatment of the substrate. In this regard, the first temperature is preferably in a range below 100° C., more preferably below 80° C. and particularly preferably below 70° C., and the second temperature is preferably in a range above 120° C., more preferably above 150° C. and particularly preferably above 180° C.

Between the insertion of the substrate into the substrate carrier and the treatment of the substrate and/or during the treatment of the substrate, the substrate is preferably held in the substrate carrier, preferably automatically, in a form-fitting and force-free manner by a plurality of locking devices.

According to a first variant, the substrate can be oriented substantially vertically during the treatment step and preferably also during the insertion of the substrate into the substrate carrier and/or during the removal of the substrate from the substrate carrier. In this case, the centering device is preferably located in the lower half and particularly preferably in the lower third of the substrate. It is further preferred that then essentially no frictional forces act between the substrate and the substrate carrier during the step of the insertion of the substrate into the substrate carrier and/or during the step of the removal of the substrate from the substrate carrier. This can be achieved, for example, in that during the insertion of the substrate into the substrate carrier the substrate is inserted into the substrate carrier in a manner inclined with respect to a plane defined by the substrate carrier such that first the lower edge of the substrate rests on a lower side of the substrate carrier and subsequently the substrate is tilted, preferably without friction, into the plane of the substrate carrier. This is preferably done by means of a robot. A relatively small inclination of the substrate with respect to the plane defined by the substrate carrier can be sufficient, for example an angle of at least 1°, preferably at least 5° or particularly preferably at least 15°. Analogously, it is preferred that during the removal of the substrate from the substrate carrier, the substrate is first tilted out of the plane defined by the substrate carrier so that only the lower edge of the substrate rests on a lower side of the substrate carrier, and subsequently the substrate is removed in the tilted state, preferably without friction. This is also preferably done by means of a robot.

### BRIEF DESCRIPTION OF THE DRAWINGS

In the following, the present invention is explained in more detail with reference to the Figures, in which

FIG. 1 shows a top view of a substrate carrier of the invention according to a preferred embodiment;

FIG. 2 shows the spring of a centering device of the invention according to a preferred embodiment in the open position;

FIG. 3 shows the spring of FIG. 2 in the closed position;

FIG. 4 shows a cross-sectional view of a substrate carrier of the invention according to a preferred embodiment;

FIG. 5 shows a detailed view of FIG. 4;

FIG. 6 shows a view analogous to FIG. 5, but with the substrate offset;

FIG. 7 shows a top view of a substrate carrier of the invention according to a further preferred embodiment;

FIG. 8 shows a perspective view of the movement elements for a centering device of a changing station of the invention according to a preferred embodiment;

FIG. 9 shows a perspective view of the movement elements for a locking device of a changing station according to a preferred embodiment,

FIG. 10 shows a vertical cross-section through a substrate in the substrate carrier according to a preferred embodiment; and

FIG. 11 shows a vertical cross-section through the substrate of FIG. 10 during the removal.

### DETAILED DESCRIPTION

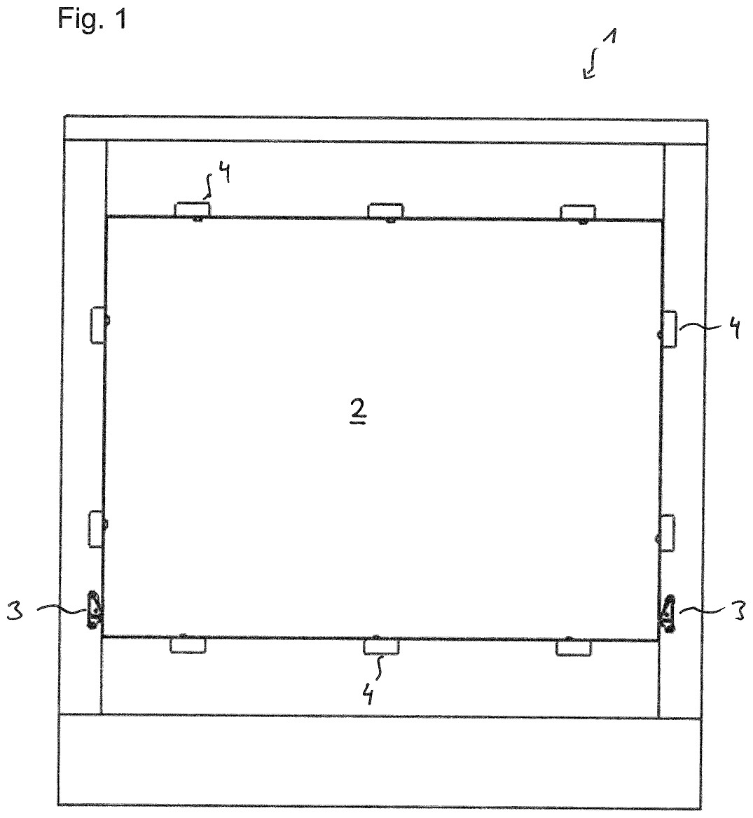

FIG. 1 shows a preferred embodiment of a substrate carrier 1 according to the invention in a top view. A substrate 2 is already accommodated in the substrate carrier 1, said substrate 2 being held in the substrate carrier 1 in a form-fitting and force-free manner by means of a plurality of locking devices 4. Although ten locking devices 4 are depicted in the illustrated embodiment, it should be appreciated that fewer or more locking devices can also be provided in other symmetrical or asymmetrical arrangements. The substrate carrier 1 further comprises a centering device adapted to center the substrate along a first axis, wherein the centering device comprises two inwardly preloaded springs 3 opposite each other.

In the illustrated preferred embodiment, the substrate 2 is oriented substantially vertically in the substrate carrier 1 so that the substrate 2 rests on the substrate carrier 1 at its lower edge, which extends parallel to the first axis between the two springs 3. In such an arrangement, the vertical orientation of the substrate 2 with respect to the substrate carrier 1 is actually defined by the fact that the substrate 2 rests on the substrate carrier at its lower edge. A centration takes place only in the horizontal direction, i.e., along the first axis extending between the two springs 3. For this purpose, at least two springs 3 opposite each other are required at the respective vertical side edges of the substrate 2, which are preferably each arranged at the same height with respect to the lower edge of the substrate 2. Preferably, the springs 3 of the centering device are located in the vicinity of the lower edge, as shown in FIG. 1. This enables the forces to act in the lower region of the substrate 2 for its centration. However, the springs can also be provided further up. Furthermore, two or more pairs of springs opposite each other can also be provided.

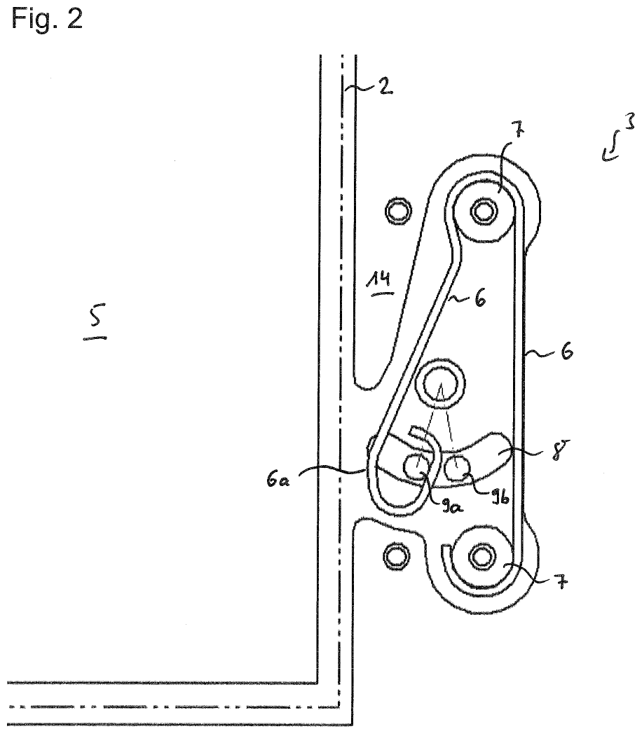

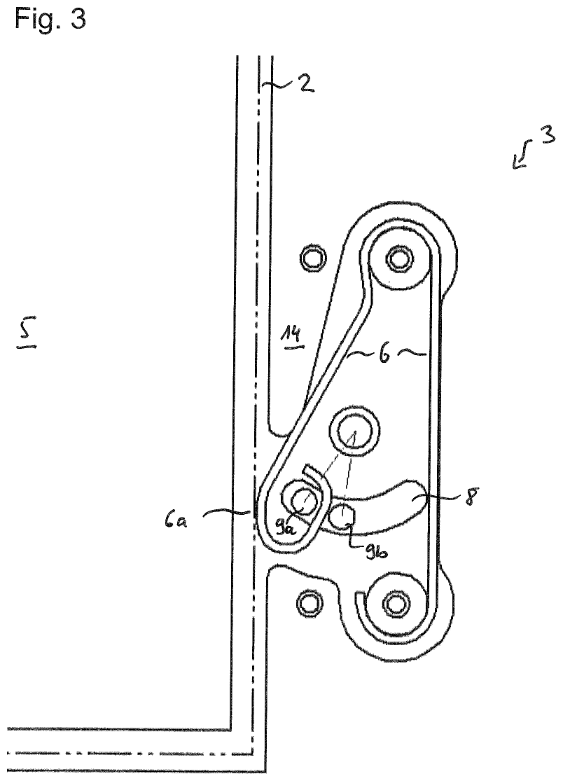

In FIGS. 2 and 3, the right one of the two centering springs 3 of FIG. 1 is shown in detail, once in the open position (cf. FIG. 2) and once in the closed position (cf. FIG. 3). The spring 3 comprises a curved spring element 6 which is mounted on two mountings 7. Said spring element 6 comprises a contact area 6a which is provided to come into contact with the substrate 2 at its side edge. As can be seen in FIG. 2, said contact area has a curvature whose radius of curvature is preferably at least 5 mm. In the depicted preferred embodiment, the movable end of the spring element 6 ends in the region of the contact area 6a in a loop or hook which comprises or forms an accommodating area for a first movement element 9a. Said first movement element 9a can be part of a changing station, which will be explained in the following. In the depicted embodiment, the first movement element 9a is essentially a pin that can plunge into the loop or curve or hook of the spring element 6. In the open spring position shown in FIG. 2, the spring element 6 is held in the outwards or rightwards deflected position against its preload by means of said pin 9a so that the contact area 6a does not contact the side edge of the substrate 2. In this position of the spring 3, the substrate 2 can be easily inserted into or removed from the substrate carrier without interaction with the spring 3.

As soon as the substrate 2 has been inserted into the substrate carrier 1, the pin 9a is moved to the left along the elongated hole 8 on a circular path (cf. FIG. 3) so that the spring element 6 springs inwards or leftwards due to its preload and the contact area 6a comes into contact with a side edge of the substrate 2. In order to ensure that the spring element 6 does not get jammed or twisted, a second movement element 9b can be provided which is moved along the curved elongated hole 8 together with the first movement element 9a and, in the depicted preferred embodiment, presses onto the loop or hook of the spring element 6 from the outside to move the spring element 6 into the position shown in FIG. 3. Subsequently, the two pins 9a and 9b can be removed from the corresponding accommodating areas of the spring 3, since the spring element 6 now acts on the side edge of the substrate 2 solely due to its preload.

In FIG. 3, a situation is illustrated in which the contact area 6a of the spring element 6 of the spring 3 just comes into contact with a side edge of the substrate 2 without exerting a substantial force on the substrate 2, since the movable end of the spring element 6 rests against the stop 14 in the position depicted in FIG. 3. If, however, starting from the position depicted in FIG. 3, the substrate 2 were now to expand along the first axis, i.e. here in the horizontal direction (or the substrate carrier 1 were to contract accordingly), the right-hand side edge of the substrate 2 would push the contact area 6a of the spring element 6 outwards or rightwards so that the spring element 6 no longer rests against the stop 14. The spring force then exerted by the spring element 6 onto the side edge of the substrate 2 (as well as the corresponding force of the opposite spring element) would then ensure a symmetrical or centered arrangement of the substrate 2 in the substrate carrier 1.

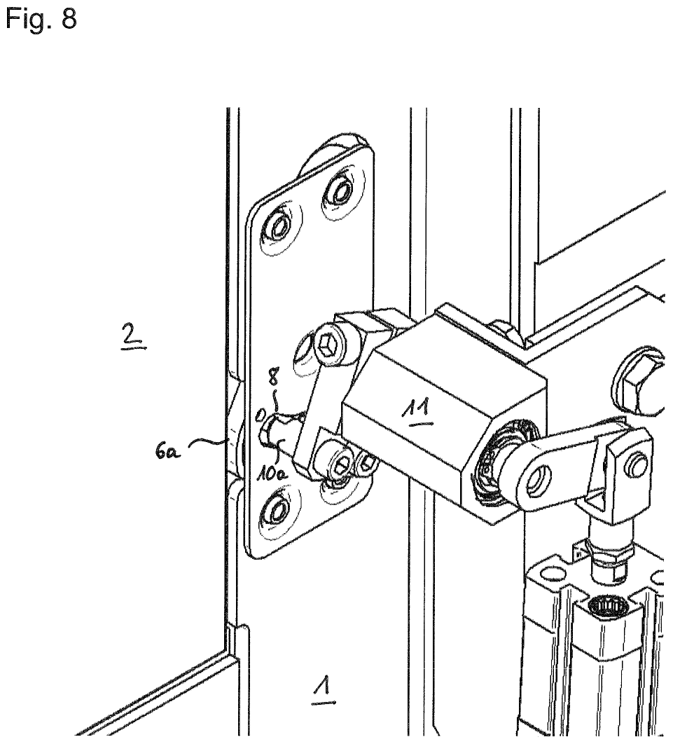

In FIG. 8, a corresponding actuator 11 of a changing station for opening and closing the springs is illustrated a perspective view, said changing station being not further illustrated and being known per se. The actuator 11 is provided with two movement elements, of which the first movement element 10a is clearly visible. Said first movement element 10a projects through the curved elongated hole 8 into the loop formed by the spring element 6 in the region of the contact area 6a, as previously discussed with reference to FIGS. 2 and 3. The actuator 11 causes the two movement elements or pins to move along the elongated hole 8, as described above. A further actuator, not shown, can retract the two movement elements from the corresponding accommodating areas 9a and 9b of the spring.

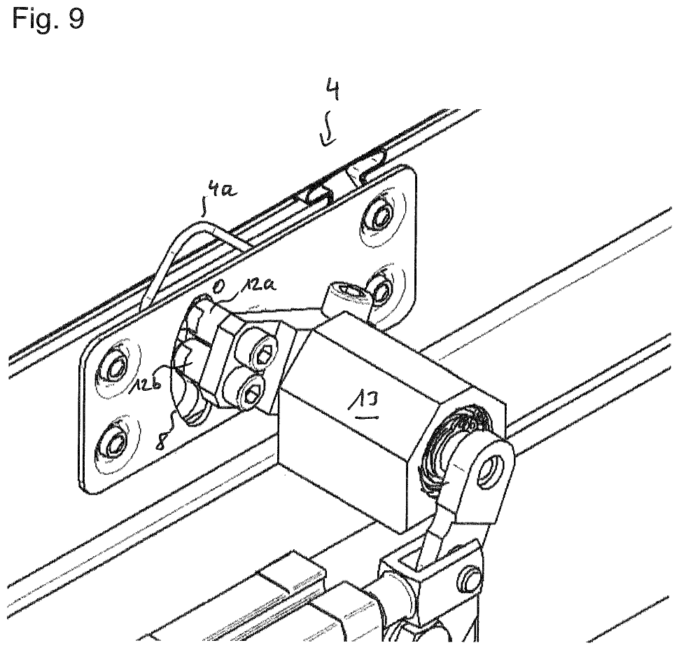

A corresponding actuator 13 and corresponding engagement elements or pins 12a and 12b can be provided for opening and closing the locking devices 4 (cf. FIG. 9). For opening and closing by means of the pins 12a and 12b, the actuator 13 moves the locking loop 4a shown in FIG. 9, which secures the substrate, for example, against tipping out of the substrate carrier.

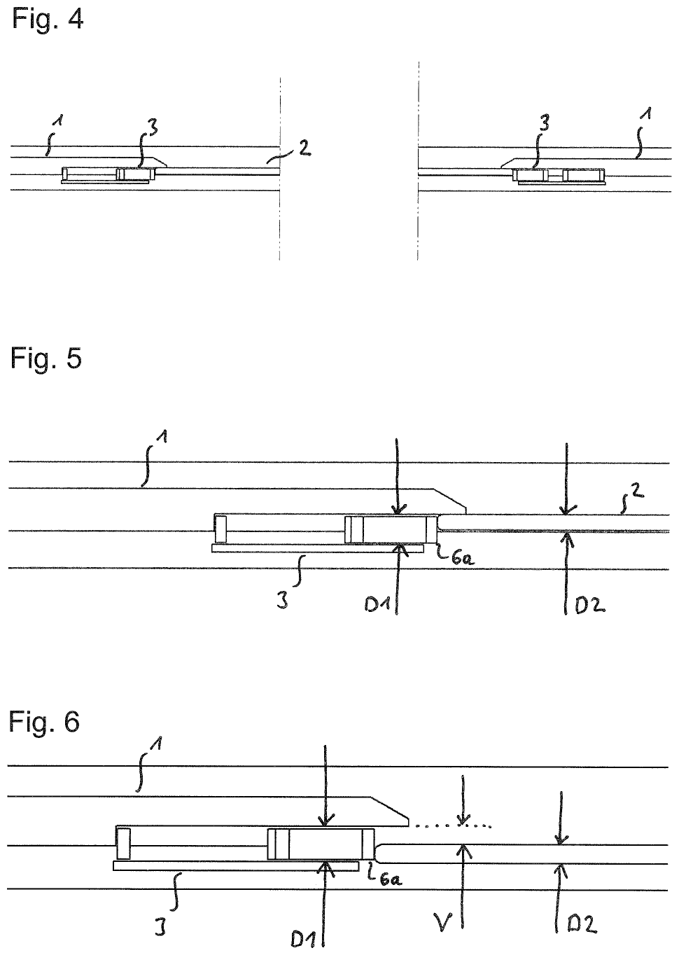

FIG. 4 shows a sectional view of the substrate carrier according to FIG. 1 along the first axis. As can be clearly seen there, the substrate 2 rests against the substrate carrier 1 at its side edges and the two opposite (here vertical) side edges of the substrate 2 are in contact with the contact areas 6a of the spring element 6 of the two springs 3.

FIG. 5 shows an enlarged detail for the left spring 3, where it can be clearly seen that the left side edge of the substrate 2 directly rests against the contact area 6a of the spring 3. It is preferred that, in the contact area 6a perpendicular to the substrate surface, the extension or thickness D1 of the spring 3 is significantly greater than the thickness D2 of the substrate.

As already explained, the ratio between D1 and D2 is preferably at least 1.5 and particularly preferably at least 2.

The advantage of this feature can be seen in FIG. 6, which is analogous to FIG. 5, wherein, however, the substrate 2 is here offset downwards by an offset V, which can be caused, for example, by a curvature of the substrate. Since the thickness D1 is greater than the thickness D2, the outer edge of the substrate 2 still rests against the contact area 6a of the spring 3 in this situation, so that a centration by the spring 3 can still be ensured.

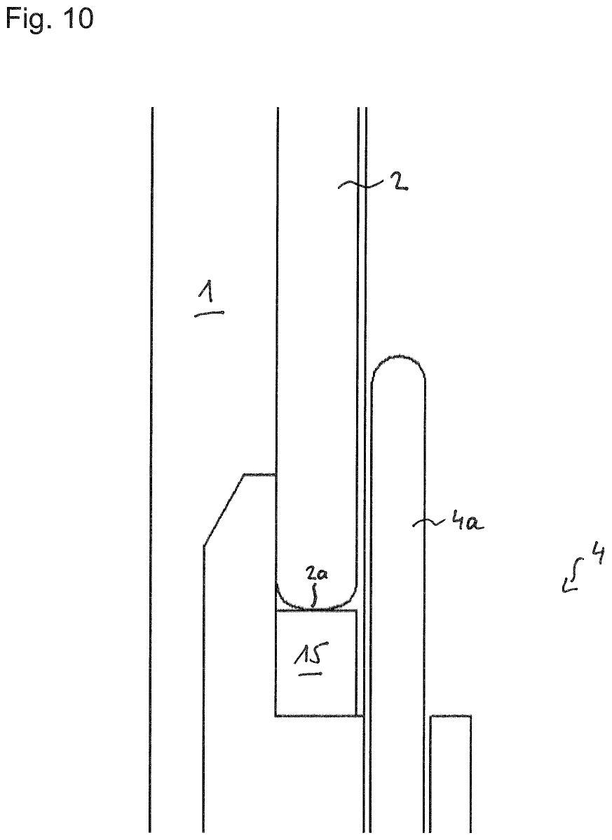

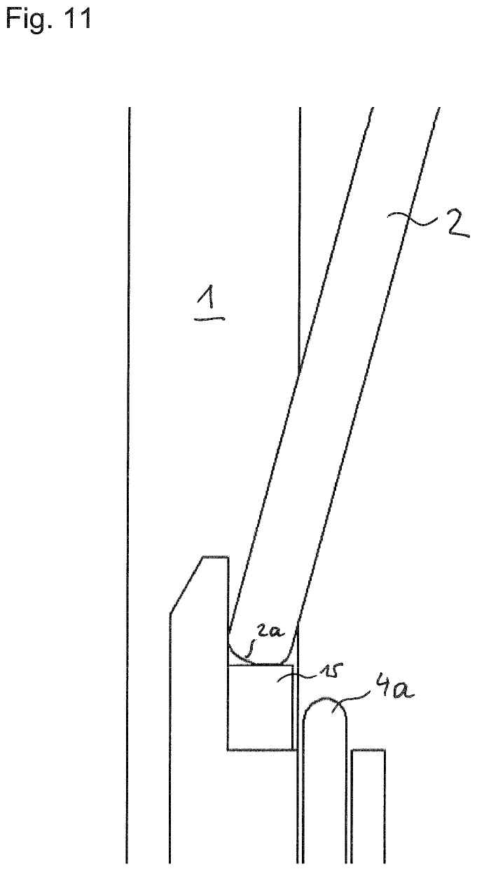

The substrate carrier according to the invention enables, i.a., a frictionless removal of a substrate from the substrate carrier, which will be explained with reference to the schematic cross-sectional views of FIGS. 10 and 11. FIG. 10 shows a vertical cross-section through a substrate 2 in the substrate carrier 1 according to a preferred embodiment, wherein the substrate 2 rests on the substrate carrier 1 at its lower edge 2a. In the illustrated preferred embodiment, the substrate carrier comprises, in the region of the contact surface, a strip 15 made of a material with a low coefficient of static friction in order to minimize the static friction force between the substrate and the substrate carrier. In the situation illustrated in FIG. 10, the substrate is secured against tipping out of the substrate carrier by means of the locking loop 4a (cf. also FIG. 9) of the locking device 4. The actuator 13 shown in FIG. 9 now moves the locking loop 4a downwards to open the locking device 4 (cf. FIG. 11). In this state, the substrate can now first be tilted out of the (here: vertical) plane defined by the substrate carrier, preferably by means of a robot, so that only the lower edge 2a of the substrate 2 rests on a lower side 15 of the substrate carrier, as shown in FIG. 11. Subsequently, the substrate can be removed in the tilted state, preferably without friction. In an analogous manner, the substrate can be inserted into the substrate carrier without friction.

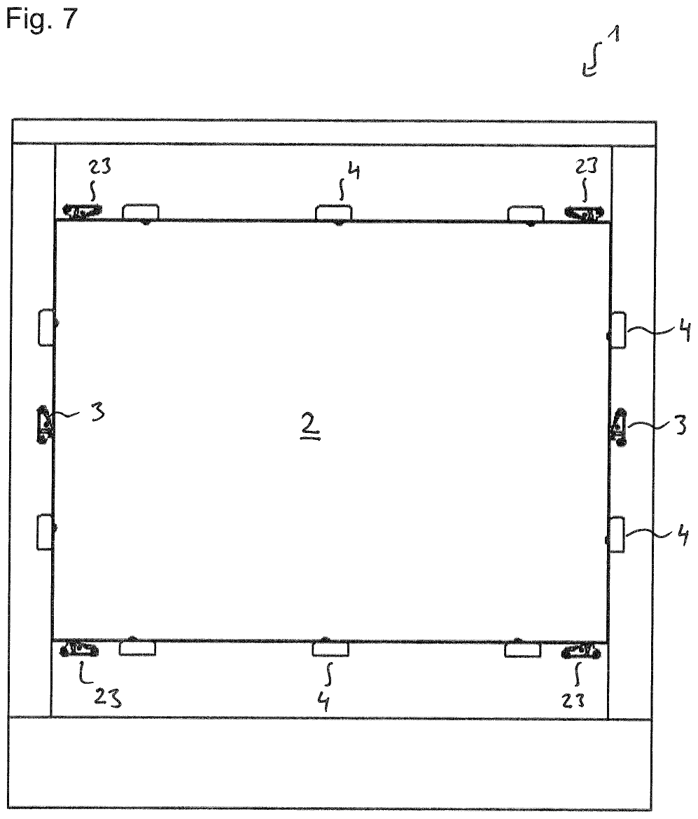

Instead of a vertical orientation of the substrate, the substrate can also be oriented substantially horizontally in the substrate carrier, as exemplarily shown in FIG. 7. In this case, however, it is preferred that, in addition to the two springs 3 of the first centering device, a further centering device with two pairs of inwardly preloaded springs 23 opposite each other is provided which is adapted to center the substrate along a second axis which is perpendicular to the first axis. The arrangement of the springs 3 and 23 in FIG. 7 is exemplary, wherein, however, the symmetrical arrangement is preferred.

In the preferred embodiments shown, the springs are configured as leaf springs. However, other types of springs can also be used in the context of the present invention. However, it is preferred that the spring can be easily assembled and disassembled by simply clipping it on.

1. A substrate carrier for accommodating and transporting a substrate, wherein the substrate carrier comprises a centering device adapted to center the substrate along a first axis, wherein the centering device comprises two inwardly preloaded springs opposite each other.

2. The substrate carrier according to claim 1, wherein each of the springs comprises a contact area which is provided to come into contact with the substrate, wherein the contact area has a radius of curvature of at least 5 mm.

3. The substrate carrier according to claim 1, wherein each of the springs comprises an accommodating area for a first movement element and wherein the springs can be moved outwards by means of the first movement elements.

4. The substrate carrier according to claim 1, further comprising a substrate that is accommodated in the substrate carrier, wherein each of the springs comprises a contact area provided to come into contact with the substrate, wherein, in the contact area in the direction of the substrate thickness, the spring has an extension that is greater than the thickness of the substrate.

5. The substrate carrier according to claim 4, wherein the substrate is oriented substantially vertically in the substrate carrier and wherein the substrate rests on the substrate carrier at its lower edge extending parallel to the first axis, wherein a static friction force exists between the lower edge of the substrate and the substrate carrier and wherein a decentration of the substrate along the first axis by 2 mm generates a resultant force of the two springs onto the substrate that is greater than the static friction force.

6. The substrate carrier according to claim 1, further comprising a plurality of locking devices adapted to hold the substrate in the substrate carrier in a form-fitting and force-free manner.

7. The substrate carrier according to claim 1, further comprising a further centering device adapted to center the substrate along a second axis, wherein the further centering device comprises two pairs of inwardly preloaded springs opposite each other.

8. The substrate carrier according to claim 5, wherein the coefficient of static friction is less than 0.2

9. A changing station comprising a substrate carrier according to claim 1.

10. The changing station according to claim 9, wherein each of the springs comprises an accommodating area for a first movement element and wherein the changing station comprises two or more first movement elements adapted to move the springs outwards.

11. A method for treating a substrate comprising the following steps:
(a) inserting a substrate into a substrate carrier according to claim 1; and
(b) treating the substrate.

12. The method according to claim 11, wherein, prior to the insertion of the substrate, the springs of the centering device are moved outwards, wherein the substrate carrier comprises a plurality of locking devices adapted to hold the substrate in the substrate carrier in a form-fitting and force-free manner, and wherein, prior to the insertion of the substrate, the locking devices are opened.

13. The method according to claim 11, wherein, after the insertion of the substrate, the springs of the centering device are moved inwards, wherein the substrate carrier comprises a plurality of locking devices adapted to hold the substrate in the substrate carrier in a form-fitting and force-free manner, and wherein, after the insertion of the substrate, the locking devices are closed.

14. The method according to claim 11, further comprising the step:
(c) removing the substrate from the substrate carrier.

15. The method according to claim 14, wherein, prior to the removal of the substrate, the springs of the centering device are moved outwards, wherein the substrate carrier comprises a plurality of locking devices adapted to hold the substrate in the substrate carrier in a form-fitting and force-free manner, and wherein the locking devices are opened prior to the removal of the substrate.

16. The method according to claim 11, wherein the substrate carrier and/or the substrate are heated from a first temperature to a second temperature between steps (a) and (b), wherein the first temperature is in a range below 100° C. and wherein the second temperature is in a range above 120° C.

17. The method according to claim 11, wherein, between steps (a) and (b), the substrate is held in the substrate carrier in a form-fitting and force-free manner by means of a plurality of locking devices.

18. The method according to claim 11, wherein the substrate is oriented substantially vertically in step (b), wherein the centering device is located in the lower half of the substrate.

19. The method according to claim 18, wherein no frictional forces act between the substrate and the substrate carrier during steps (a) and/or (c).

20. The method according to claim 19, wherein in step (a) the substrate is inserted into the substrate carrier in a manner inclined with respect to a plane defined by the substrate carrier such that first the lower edge of the substrate rests on a lower side of the substrate carrier and subsequently the substrate is tilted into the plane of the substrate carrier.
